(19) United States
(12) Patent Application Publication
(10) Pub. No.: US 2007/0233926 A1
(43) Pub. Date: Oct. 4, 2007

(54) Bus width automatic adjusting method and system

(75) Inventor: Chao-Huang Chang, Taipei (TW)

Correspondence Address: EDWARDS ANGELL PALMER & DODGE LLP, P.O. BOX 55874, BOSTON, MA, 02205, US

(73) Assignee: Inventec Corporation, Taipei (TW)

(21) Appl. No.: 11/373,561

(22) Filed: Mar. 10, 2006

(51) Int. Cl. H05K 7/10; G06F 13/40

(52) U.S. Cl. 710/301; 710/307

(57) ABSTRACT

A bus width automatic adjusting method and system is proposed, which is designed for use with a computer platform for providing the computer platform with a bus width automatic adjusting function; and which is characterized by dividing the bus of the interface controller on the computer platform and the bus of each connecting slot into two half-width portions such that the two half-width portions of the bus of the interface controller can be selectively connected to either just one slot or two slots depending on the current card plugging status of the slots on the motherboard of the computer platform. This feature allows the user to plug just one circuit card to one connecting slot on the motherboard or two circuit cards respectively to two connecting slots on the motherboard, and notwithstanding allow the plugged circuit board(s) to function normally and operate at the optimal data transmission rate.

### BACKGROUND OF THE INVENTION

1. Field of the Invention

This invention relates to computer hardware technology, and more particularly, to a bus width automatic adjusting method and system which is designed for use in conjunction with a computer platform, such as a desktop computer or a network server, for providing the computer platform with a bus width automatic adjusting function.

2. Description of Related Art

PCI (Peripheral Component Interconnect) is a standard peripheral bus architecture that is widely utilized on computer platforms, such as desktop computers, notebook computers, network servers, and so on, for connecting the CPU (Central Processing Unit) of the computer platform externally to circuit cards that can be used for connections to various kinds of peripheral devices, such as monitor adapters, hard disk drives, CD-DVD drivers, network adapters, to name just a few. With the advances in computer technology, the PCI standard is further evolved to include an extended subset called PCIe (PCI Express) which allows an enhanced performance in data transmission speed.

The PCIe standard supports various bus widths for connections to PCIe-compliant circuit cards, including 1 bit (×1), 4 bits (×4), 8 bits (×8), and 16 bits (×16). This feature allows a circuit card having a smaller bus width, such as 4bits, to be pluggable to a PCIe-compliant slot having a larger bus width, such as 8 bits or 16 bits. In other words, if a computer motherboard is equipped with a PCIe interface controller having an 8-bit bus, then the PCIe interface controller can be selectively connected to either an 8-bit circuit card or a 4-bit circuit card.

In practical implementation, however, one problem to the above-mentioned PCIe bus architecture is that if a PCIe interface controller has an 8-bit bus, then in circuit design, the 8-bit bus can only be used in the following 2 ways: first, connecting all the 8-bit bus lines to one single slot; and second, dividing the 8-bit bus into two 4-bit portions for use to be connected to two slots respectively. If the second method is employed, then every circuit board plugged in the slot, irrespective of its bus width, can only utilize 4 bits of the bus for data communication. In other words, even if there is just one circuit card installed on the motherboard and which has a bus width of 8 bits, the 8-bit circuit card can nonetheless use a half-width bus of 4 bits for data communication with the PCIe interface controller. For this sake, in the case that the motherboard is installed with just one circuit board, the performance of data transmission will be degraded.

### SUMMARY OF THE INVENTION

It is therefore an objective of this invention to provide a bus width automatic adjusting method and system which can provide a PCIe interface controller with a bus width automatic adjusting function that allows the PCIe interface controller to automatically adjust the width of the bus in response to different card plugging conditions of the connecting slots on the motherboard so as to allow the PCIe interface controller to always have optimal performance in data communication with the plugged circuit card(s).

The bus width automatic adjusting method and system according to the invention is designed for use in conjunction with a computer platform, such as a desktop computer or a network server, for providing the computer platform with a bus width automatic adjusting function for the purpose of allowing the plugged circuit cards on the computer platform's motherboard to always have optimal performance in data communication with the computer platform.

The bus width automatic adjusting method according to the invention comprises: (1) in the event that the first circuit card slot and the second circuit card slot are both positive in card plugging status, connecting the first half-portion bus of the interface controller to the first half-portion bus of the first circuit card slot, and meanwhile connecting the second half-portion bus of the interface controller to the first half-portion bus of the second circuit card slot; (2) in the event that the first circuit card slot is positive in card plugging status while the second circuit card slot is negative in card plugging status, connecting the first half-portion bus of the interface controller to the first half-portion bus of the first circuit card slot, and meanwhile connecting the second half-portion bus of the interface controller to the second half-portion bus of the second circuit card slot; and (3) in the event that the first circuit card slot is negative in card plugging status while the second circuit card slot is positive in card plugging status, connecting the first half-portion bus of the interface controller to the first half-portion bus of the second circuit card slot, and meanwhile connecting the second half-portion bus of the interface controller to the second half-portion bus of the second circuit card slot.

In architecture, the bus width automatic adjusting system according to the invention comprises: (A) a switching control signal generating module, which is capable of detecting the card plugging status of the first circuit card slot and the second circuit card slot, and if positive, capable of generating a corresponding set of switching control signals; and (B) a switching module, which is capable of responding to the switching control signals from the switching control signal generating module by switching the interconnection of the interface controller with the first circuit card slot and the second circuit card slot in such a manner that: in the event that the first circuit card slot and the second circuit card slot are both positive in card plugging status, the first half-portion bus of the interface controller is connected to the first half-portion bus of the first circuit card slot, and the second half-portion bus of the interface controller is connected to the first half-portion bus of the second circuit card slot; in the event that the first circuit card slot is positive in card plugging status while the second circuit card slot is negative in card plugging status, the first half-portion bus of the interface controller is connected to the first half-portion bus of the first circuit card slot, and the second half-portion bus of the interface controller is connected to the second half-portion bus of the second circuit card slot; and in the event that the first circuit card slot is negative in card plugging status while the second circuit card slot is positive in card plugging status, the first half-portion bus of the interface controller is connected to the first half-portion bus of the second circuit card slot, and the second half-portion bus of the interface controller is connected to the second half-portion bus of the second circuit card slot.

The bus width automatic adjusting method and system according to the invention is characterized by dividing the bus of the interface controller on the computer platform and the bus of each connecting slot into two half-width portions such that the two half-width portions of the bus of the interface controller can be selectively connected to either just one slot or two slots depending on the current card plugging status of the slots on the motherboard of the computer platform. This feature allows the user to plug just one circuit card to one connecting slot on the motherboard or two circuit cards respectively to two connecting slots on the motherboard, and notwithstanding allow the plugged circuit board(s) to function normally and operate at the optimal data transmission rate.

### BRIEF DESCRIPTION OF DRAWINGS

The invention can be more fully understood by reading the following detailed description of the preferred embodiments, with reference made to the accompanying drawings, wherein:

FIG. 1 is a schematic diagram showing the application of the bus width automatic adjusting system according to the invention;

FIG. 2 is a schematic diagram showing the internal architecture of the bus width automatic adjusting system according to the invention;

FIG. 3 is a schematic diagram showing a preferred embodiment of a switching control signal generating module utilized by the bus width automatic adjusting system of the invention; and

FIG. 4 is a truth table showing the switching actions performed by a switching module in relation to the logic states of a set of switching control signals.

### DETAILED DESCRIPTION OF PREFERRED EMBODIMENTS

The bus width automatic adjusting method and system according to the invention is disclosed in full details by way of preferred embodiments in the following with reference to the accompanying drawings.

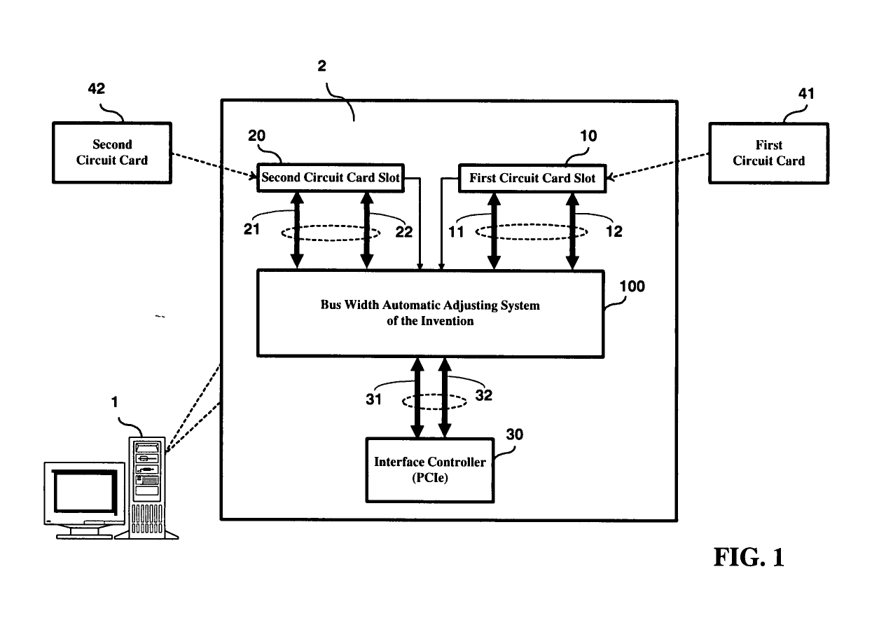

FIG. 1 is a schematic diagram showing the application of the bus width automatic adjusting system according to the invention (as the block indicated by the reference numeral 100). As shown, the bus width automatic adjusting system of the invention 100 is designed for use in conjunction with a computer platform 1, such as a desktop computer or a network server, for integration to the motherboard 2 of the computer platform 1 that is equipped with a special type of bus architecture having at least one interface controller 30 and at least two circuit card slots, including a first circuit card slot 10 and a second circuit card slot 20. In accordance with the invention, the first circuit card slot 10 is connected to a bus that is divided into a first half-portion bus 11 and a second half-portion bus 12; the second circuit card slot 20 is connected to a bus that is divided into a first half-portion bus 21 and a second half-portion bus 22; and the interface controller 30 is connected to a bus that is divided into a first half-portion bus 31 and a second half-portion bus 32 (note that for simplification of the drawings, FIG. 1 only demonstratively shows two circuit card slots and those components that are related to the invention; but in practice, the motherboard 2 can include a number of various other components, such processors, memories, to name just a few). In practical implementation, for example, the computer platform 1 is a desktop computer or a network server, while the interface controller 30 is a PCIe (PCI Express, where PCI=Peripheral Component Interconnect) compliant interface controller. The first circuit card slot 10, the second circuit card slot 20, and the interface controller 30 each have a full bus width of 8 bits, and therefore the first half-portion buses 11, 21, 31 and the second half-portion buses 12, 22, 32 thereof each have a width of 4 bits. However, it is to be noted that the bus width automatic adjusting system of the invention 100 is applicable to any bus widths, i.e., the full bus width is not limited to 8 bits, but can also be 12 bits, 16 bits, 24 bits, 32 bits, 64 bits, or more.

During actual operation, the bus width automatic adjusting system of the invention 100 is capable of responding to the current card plugging status of the first circuit card slot 10 and the second circuit card slot 20 by selectively connecting the first half-portion bus 31 and the second half-portion bus 32 of the PCIe interface controller 30 to the first half-portion bus 11 and the second half-portion bus 12 of the first circuit card slot 10 and the first half-portion bus 21 and the second half-portion bus 22 of the second circuit card slot 20. The switching actions performed by the fan unit driving control system of the invention 100 include the following 3 modes of operation:

(1) Switching Operation Mode 1

This switching operation mode is activated in response to an event that the first circuit card slot 10 and the second circuit card slot 20 are both positive in card plugging status, i.e., a first circuit card 41 is plugged in the first circuit card slot 10 and meanwhile a second circuit card 42 is plugged in the second circuit card slot 20. In this mode, the first half-portion bus 31 of the interface controller 30 is connected to the first half-portion bus 11 of the first circuit card slot 10, and the second half-portion bus 32 of the interface controller 30 is connected to the first half-portion bus 21 of the second circuit card slot 20. This switching operation effectively causes both the first circuit card 41 and the second circuit card 42 to utilize a 4-bit bus width (i.e., half-width bus) for data communication with the PCIe interface controller 30.

(2) Switching Operation Mode 2

This switching operation mode is activated in response to an event that the first circuit card slot 10 is positive in card plugging status while the second circuit card slot 20 is negative in card plugging status, i.e., a first circuit card 41 is plugged in the first circuit card slot 10, and meanwhile no circuit card is plugged in the second circuit card slot 20. In this mode, the first half-portion bus 31 of the interface controller 30 is connected to the first half-portion bus 11 of the first circuit card slot 10, and the second half-portion bus 32 of the interface controller 30 is connected to the second half-portion bus 12 of the first circuit card slot 10. This switching operation effectively causes the first circuit card 41 plugged in the first circuit card slot 10 to utilize an 8-bit bus width (i.e., full-width bus) for data communication with the PCIe interface controller 30.

(3) Switching Operation Mode 3

This switching operation mode is activated in response to an event that the first circuit card slot 10 is negative in card plugging status while the second circuit card slot 20 is positive in card plugging status, i.e., no circuit card is plugged in the first circuit card slot 10, and meanwhile a circuit card 42 is plugged in the second circuit card slot 20. In this mode, the first half-portion bus 31 of the interface controller 30 is connected to the first half-portion bus 21 of the second circuit card slot 20, and the second half-portion bus 32 of the interface controller 30 is connected to the second half-portion bus 22 of the second circuit card slot 20. This switching operation effectively causes the circuit card 42 plugged in the second circuit card slot 20 to utilize an 8-bit bus width (i.e., full-width bus) for data communication with the PCIe interface controller 30.

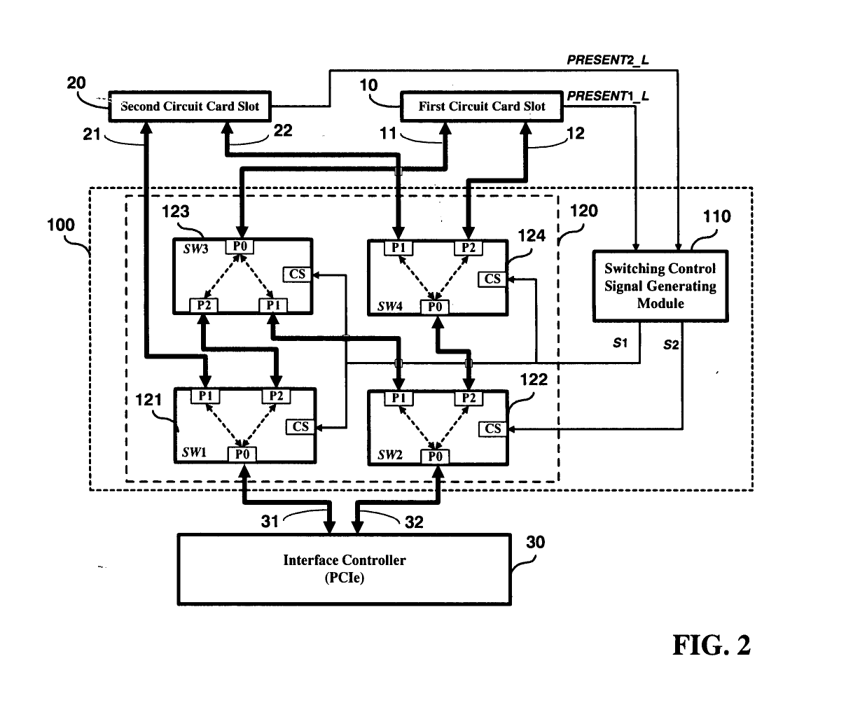

As shown in FIG. 2, in architecture, the bus width automatic adjusting system of the invention 100 is based on a modularized component model which comprises: (A) a switching control signal generating module 110; and (B) a switching module 120. The respective attributes and behaviors of the constituent components 110, 120 of the bus width automatic adjusting system of the invention 100 are described in details in the following

The switching control signal generating module 110 is designed to detect the card plugging status of the first circuit card slot 10 and the second circuit card slot 20, i.e., whether the first circuit card slot 10 and the second circuit card slot 20 are plugged with circuit cards 41, 42;

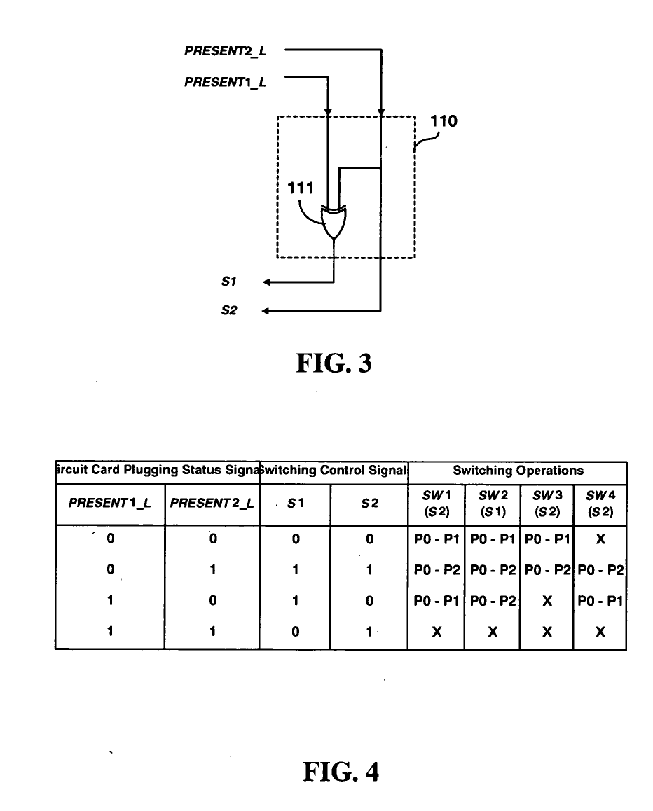

and if positive, capable of generating a corresponding set of switching control signals [S1, S2]. In practical implementation, for example, the switching control signal generating module 110 is designed to utilize a card present signal (denoted by PRESENT1_L) from the first circuit card slot 10 and another card present signal (denoted by PRESENT2_L) to judge the current card plugging status of the first circuit card slot 10 and the second circuit card slot 20. Specifically, when a first circuit card 41 is plugged in the first circuit card slot 10, it will for example cause a break in the connection of a system voltage (V_{DD}), which is for example a 3.3 V (volt) voltage, to thereby output a logic-LOW voltage signal PRESENT1_L used to indicate that the first circuit card slot 10 is currently positive in card plugging status; i.e., when PRESENT1_L=0, it indicates that the first circuit card slot 10 is positive in card plugging status; and when PRESENT1_L=1, it indicates that the first circuit card slot 10 is negative in card plugging status. In a similar manner, when a second circuit card 42 is plugged in the second circuit card slot 20, it will output a logic-LOW voltage signal PRESENT2_L used to indicate that the second circuit card slot 20 is currently positive in card plugging status; i.e., when PRESENT2_L=0, it indicates that the first circuit card slot 10 is positive in card plugging status; and when PRESENT1_L=1, it indicates that the second circuit card slot 20 is negative in card plugging status. It is to be noted that the use of logic-LOW voltage state or logic-HIGH voltage state to represent whether the first circuit card slot 10 and second circuit card slot 20 are positive or negative in card plugging status is an arbitrary design choice; i.e., in practice, it can be alternatively implemented in such a manner as to use logic-HIGH voltage state to indicate positive card plugging status and logic-LOW voltage state to indicate negative card plugging status. During actual operation, the switching control signal generating module 110 is capable of responding to the card plugging status indicating signals [PRESENT1_L, PRESENT2_L] by generating a corresponding set of switching control signals [S1, S2], where S1=(PRESENT1_L) XOR (PRESENT2_L), and S2=PRESENT2_L. FIG. 3 shows a preferred embodiment of the internal circuit structure of the switching control signal generating module 110, which utilizes an XOR gate 111 to implement the exclusive-OR operation of S1=(PRESENT1_L) XOR (PRESENT2_L); and FIG. 4 is a truth table showing the logic relationships between [S1, S2] and [PRESENT1_L, PRESENT2_L].

The switching module 120 is designed to respond to the switching control signals [S1, S2] from the switching control signal generating module 110 by switching the interconnection of the interface controller 30 with the first circuit card slot 10 and the second circuit card slot 20 in one of the above-mentioned 3 switching operation modes. In implementation, as illustrated in FIG. 2, this switching module 120 is implemented by using four two-way switches, including a first switch (SW1) 121, a second switch (SW2) 122, a third switch (SW3) 123, and a fourth switch (SW4) 124; and these switches 121, 122, 123, 124 are all identically structured with a base connecting port P0, a first-way connecting port P1, a second-way connecting port P2, and a control port CS; wherein the three connecting ports P0, P1, P2 are all designed for connection to a half-width bus (i.e., a 4-bit bus).

The first switch (SW1) 121 is connected in such a manner that its base connecting port P0 is connected to the first half-portion bus 31 of the PCIe interface controller 30; its first-way connecting port P1 is connected to the first half-portion bus 21 of the second circuit card slot 20; its second-way connecting port P2 is connected to the second-way connecting port P2 of the third switch (SW3) 123; and its control port CS is connected to receive the second switching control signal S2 from the switching control signal generating module 110.

The second switch (SW2) 122 is connected in such a manner that its base connecting port P0 is connected to the second half-portion bus 32 of the PCIe interface controller 30; its first-way connecting port P1 is connected to the first-way connecting port P1 of the third switch (SW3) 123; its second-way connecting port P2 is connected to the base connecting port P0 of the fourth switch (SW4) 124; and its control port CS is connected to receive the first switching control signal S1 from the switching control signal generating module 110.

The third switch (SW3) 123 is connected in such a manner that its base connecting port P0 is connected to the first half-portion bus 11 of the first circuit card slot 10; its first-way connecting port P1 is connected to the first-way connecting port P1 of the second switch (SW2) 122; its second-way connecting port P2 is connected to the second-way connecting port P2 of the first switch (SW1) 121; and its control port CS is connected to receive the second switching control signal S2 from the switching control signal generating module 110.

The fourth switch (SW4) 124 is connected in such a manner that its base connecting port P0 is connected to the second-way connecting port P2 of the second switch (SW2) 122; its first-way connecting port P1 is connected to the second half-portion bus 22 of the second circuit card slot 20; its second-way connecting port P2 is connected to the second half-portion bus 12 of the first circuit card slot 10; and its control port CS is connected to receive the first switching control signal S1 from the switching control signal generating module 110.

Each of the above-mentioned switches 121, 122, 123, 124 operates in such a manner that when CS=0, it causes the base connecting port P0 to be linked to the first-way connecting port P1; and when CS=1, it causes the base connecting port P0 to be linked to the second-way connecting port P2. The table of FIG. 4 shows the switching actions performed by these switches 121, 122, 123, 124 in relation to the logic states of the switching control signals [S1, S2] received by the their respective control ports CS.

The following is a detailed description of 3 practical application example of the bus width automatic adjusting system of the invention 100 during actual operation. In the first application example, it is assumed that two circuit cards 41, 42 are respectively plugged in the first circuit card slot 10 and the second circuit card slot 20; in the second application example, a circuit card 41 is plugged in the first circuit card slot 10 while no circuit card is plugged in the second circuit card slot 20; and in the third application example, no circuit card is plugged in the first circuit card slot 10 while a circuit card 42 is plugged in the second circuit card slot 20.

In the first application example, when the two circuit cards 41, 42 are respectively plugged in the first circuit card slot 10 and the second circuit card slot 20, it will cause a break in the connection of a system voltage (V_{DD}), thus activating the generation of [PRESENT1_L, PRESENT2_L]=[0, 0] and thereby activating the switching control signal generating module 110 to output [S1, S2]=[0, 0]. Therefore, based on the truth table of FIG. 4, the state of [S1, S2]=[0, 0] will cause the first switch (SW1) 121, the second switch (SW2) 122, and the third switch (SW3) 123 to be switched to provide a P0-to-P1 link (the state of the fourth switch (SW4) 124 is “don't-care” and thus marked by “X” in FIG. 4). These switching actions cause the first half-portion bus 31 of the PCIe interface controller 30 to be connected to the first half-portion bus 21 of the second circuit card slot 20, and the second half-portion bus 32 of the PCIe interface controller 30 to be connected to the first half-portion bus 11 of the first circuit card slot 10, thus effectively causing both the first circuit card 41 and the second circuit card 42 to utilize a 4-bit bus width (i.e., half-width bus) for data communication with the PCIe interface controller 30.

In the second application example, in the event that a circuit card 41 is plugged in the first circuit card slot 10 and no circuit card is plugged in the second circuit card slot 20, it will cause the generation of [PRESENT1_L, PRESENT2_L]=[0, 1] and thereby activating the switching control signal generating module 110 to output [S1, S2]=[1, 1]. Therefore, based on the truth table of FIG. 4, the state of [S1, S2]=[1, 1] will cause every one of the first switch (SW1) 121, the second switch (SW2) 122, the third switch (SW3) 123, and the fourth switch (SW4) 124 to be switched to provide a P0-to-P2 link. These switching actions cause the first half-portion bus 31 of the PCIe interface controller 30 to be connected to the first half-portion bus 11 of the first circuit card slot 10, and the second half-portion bus 32 of the PCIe interface controller 30 to be connected to the second half-portion bus 12 of the first circuit card slot 10, thus effectively causing the circuit card 41 plugged in the first circuit card slot 10 to utilize an 8-bit bus width (i.e., full-width bus) for data communication with the PCIe interface controller 30.

In the third application example, in the event that no circuit card is plugged in the first circuit card slot 10 and a circuit card 42 is plugged in the second circuit card slot 20, it will cause the generation of [PRESENT1_L, PRESENT2_L]=[1, 0] and thereby activating the switching control signal generating module 110 to output [S1, S2]=[1, 0]. Therefore, based on the truth table of FIG. 4, the state of [S1, S2]=[1, 0] will cause the first switch (SW1) 121 and the fourth switch (SW4) 124 to be switched to provide a P0-to-P1 link, and meanwhile cause the second switch (SW2) 122 to be switched to provide a P0-to-P2 link (in this case, the state of the third switch (SW3) 123 is “don't-care”). These switching actions cause the first half-portion bus 31 of the PCIe interface controller 30 to be connected to the first half-portion bus 21 of the second circuit card slot 20, and the second half-portion bus 32 of the PCIe interface controller 30 to be connected to the second half-portion bus 22 of the second circuit card slot 20, thus effectively causing the circuit card 42 plugged in the second circuit card slot 20 to utilize an 8-bit bus width (i.e., full-width bus) for data communication with the PCIe interface controller 30.

The foregoing examples are based on the assumption that the full bus width of the PCIe interface controller 30 is 8 bits. However, the bus width automatic adjusting system of the invention 100 is applicable to any bus widths, such as 12 bits, 16 bits, 24 bits, 32 bits, 64 bits, or more.

In conclusion, the invention provides a bus width automatic adjusting method and system for use with a computer platform having an interface controller (such as a PCIe interface controller) for providing the PCIe interface controller with a bus width automatic adjusting function; and which is characterized by dividing the bus of the interface controller on the computer platform and the bus of each connecting slot into two half-width portions such that the two half-width portions of the bus of the interface controller can be selectively connected to either just one slot or two slots depending on the current card plugging status of the slots on the motherboard of the computer platform. This feature allows the user to plug just one circuit card to one connecting slot on the motherboard or two circuit cards respectively to two connecting slots on the motherboard, and notwithstanding allow the plugged circuit board(s) to function normally and operate at the optimal data transmission rate. The invention is therefore more advantageous to use than the prior art.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A bus width automatic adjusting method for use on a computer platform equipped with a bus architecture having at least one interface controller, a first circuit card slot, and a second circuit card slot, each being connected to a bus divided into a first half-portion bus and a second half-portion bus;
the bus width automatic adjusting method comprising:
in the event that the first circuit card slot and the second circuit card slot are both positive in card plugging status, connecting the first half-portion bus of the interface controller to the first half-portion bus of the first circuit card slot, and meanwhile connecting the second half-portion bus of the interface controller to the first half-portion bus of the second circuit card slot;
in the event that the first circuit card slot is positive in card plugging status while the second circuit card slot is negative in card plugging status, connecting the first half-portion bus of the interface controller to the first half-portion bus of the first circuit card slot, and meanwhile connecting the second half-portion bus of the interface controller to the second half-portion bus of the second circuit card slot; and
in the event that the first circuit card slot is negative in card plugging status while the second circuit card slot is positive in card plugging status, connecting the first half-portion bus of the interface controller to the first half-portion bus of the second circuit card slot, and meanwhile connecting the second half-portion bus of the interface controller to the second half-portion bus of the second circuit card slot.

2. The bus width automatic adjusting method of claim 1, wherein the computer platform is a desktop computer or a network server.

3. The bus width automatic adjusting method of claim 1, wherein the bus architecture is a PCIe (PCI Express, where PCI=Peripheral Component Interconnect) compliant bus architecture.

4. A bus width automatic adjusting system for use with a computer platform equipped with a bus architecture having at least one interface controller, a first circuit card slot, and a second circuit card slot, each being connected to a bus divided into a first half-portion bus and a second half-portion bus;
the bus width automatic adjusting system comprising:
a switching control signal generating module, which is capable of detecting the card plugging status of the first circuit card slot and the second circuit card slot, and if positive, capable of generating a corresponding set of switching control signals; and
a switching module, which is capable of responding to the switching control signals from the switching control signal generating module by switching the interconnection of the interface controller with the first circuit card slot and the second circuit card slot in such a manner that:
in the event that the first circuit card slot and the second circuit card slot are both positive in card plugging status, the first half-portion bus of the interface controller is connected to the first half-portion bus of the first circuit card slot, and the second half-portion bus of the interface controller is connected to the first half-portion bus of the second circuit card slot;
in the event that the first circuit card slot is positive in card plugging status while the second circuit card slot is negative in card plugging status, the first half-portion bus of the interface controller is connected to the first half-portion bus of the first circuit card slot, and the second half-portion bus of the interface controller is connected to the second half-portion bus of the second circuit card slot; and
in the event that the first circuit card slot is negative in card plugging status while the second circuit card slot is positive in card plugging status, the first half-portion bus of the interface controller is connected to the first half-portion bus of the second circuit card slot, and the second half-portion bus of the interface controller is connected to the second half-portion bus of the second circuit card slot.

5. The bus width automatic adjusting system of claim 4, wherein the computer platform is a desktop computer or a network server.

6. The bus width automatic adjusting system of claim 4, wherein the bus architecture is a PCIe (PCI Express, where PCI=Peripheral Component Interconnect) compliant bus architecture.

7. The bus width automatic adjusting system of claim 4, wherein the switching module includes: a first switch, a second switch, a third switch, and a fourth switch, each having a base connecting port, a first-way connecting port, a second-way connecting port, and a control port;
wherein
the first switch is connected in such a manner that its base connecting port is connected to the first half-portion bus of the interface controller; its first-way connecting port is connected to the first half-portion bus of the second circuit card slot; its second-way connecting port is connected to the second-way connecting port of the third switch; and its control port is connected to receive the second switching control signal from the switching control signal generating module;
the second switch is connected in such a manner that its base connecting port is connected to the second half-portion bus of the interface controller; its first-way connecting port is connected to the first-way connecting port of the third switch; its second-way connecting port is connected to the base connecting port of the fourth switch; and its control port is connected to receive the first switching control signal from the switching control signal generating module; and
the third switch is connected in such a manner that its base connecting port is connected to the first half-portion bus of the first circuit card slot; its first-way connecting port is connected to the first-way connecting port of the second switch; its second-way connecting port is connected to the second-way connecting port of the first switch; and its control port is connected to receive the second switching control signal from the switching control signal generating module.

8. The bus width automatic adjusting system of claim 7, wherein the switching control signal generating module includes an XOR gate for performing an exclusive-OR operation on the card plugging status signals respectively from the first circuit card slot and the second circuit card slot, and transferring the resulted signal to the control port of the second switch; and the switching control signal generating module transfers the card plugging status signal from the second circuit card slot directly to the respective control ports of the first switch, the third switch, and the fourth switch.
